(19) United States
(12) Patent Application Publication
(10) Pub. No.: US 2013/0171832 A1
(43) Pub. Date: Jul. 4, 2013

(54) Enhanced Isolation For Combinatorial Atomic Layer Deposition (ALD)

(71) Applicant: Wayne French, San Jose, CA (US)

(72) Inventor: Wayne French, San Jose, CA (US)

(73) Assignee: Intermolecular Inc., San Jose, CA (US)

(21) Appl. No.: 13/338,507

(22) Filed: Dec. 28, 2011

(51) Int. Cl. H01L 21/18; B05B 1/00

(52) U.S. Cl. 438/758; 239/589; 257/E21.085

(57) ABSTRACT

An apparatus and method for delivering fluids to a semiconductor chamber for combinatorial processing is provided. In some embodiments the apparatus is comprised of a showerhead assembly having a plurality of processing sectors separated by a purge member. The processing sectors are configured to receive one or more processing fluids for combinatorial processing on a substrate. The processing sectors are isolated by a purge fluid conveyed through the purge member. The purge member is configured to selectively control the profile of the purge fluid to enhance isolation of the processing fluids within each sector. The profile of the purge fluid is manipulated by selectively controlling the shape and/or density of the purge curtain, independently between each processing sector.

### TECHNICAL FIELD

The present disclosure relates generally to the field of semiconductor processing, and more particularly to combinatorial atomic layer deposition apparatus and methods.

### BACKGROUND

Chemical deposition processes are commonly used in the semiconductor industry to deposit a layer or film over a wafer or substrate. Chemical vapor deposition (CVD) is one such commonly used process. As device densities have continued to shrink, atomic layer deposition (ALD) has become an alternative process to CVD for the deposition of thin films.

Standard ALD processes generally provide delivery of gases to a process region in a sequential manner. In some processes, each reactant gas is introduced into a process chamber independently in a separate pulse so that mixing of the reactant gases does not occur. In each pulse a monolayer of one reactant gas is physi- or chemi-sorbed onto a surface of the substrate. After excess reactant gas is evacuated from the process chamber, a second reactant gas is then conveyed to the process chamber and reacts with the first reactant to form a monolayer of the desired film. This process may be repeated until a desired film thickness is deposited.

Traditional ALD processes and systems have been confined to processing of the full substrate, or “blanket” processing. In some instances it may be desirable to process selected regions of the substrate independently, or in a different manner. For example, it may be very valuable to independently process selected regions of the substrate in order to evaluate different materials, different unit process conditions or parameters, different sequencing and integration of processes, and combinations thereof. This capability, hereinafter referred to “combinatorial processing,” is generally not available with systems that are designed specifically for conventional full substrate processing. Moreover, it may be desirable to subject selected regions of the substrate to different processing conditions (referred to as “site-isolated deposition”) in one step, and then subject the full substrate to a similar processing condition, or a different condition, in another step.

Such combinatorial processing presents significant challenges, particularly with respect to delivery of different processing fluids to selected regions of the substrate. Traditional, or full substrate processing systems and methods, are not well suited for combinatorial processing. Accordingly, new developments are needed.

### SUMMARY

Embodiments of the present disclosure provide apparatus and methods for delivering fluids to a semiconductor chamber for combinatorial processing. In some embodiments the apparatus is comprised of a showerhead assembly having a plurality of processing sectors separated by a purge member. The processing sectors are configured to receive one or more processing fluids for combinatorial processing on a substrate. The processing sectors are isolated by a purge fluid conveyed through the purge member. The purge member is configured to control the profile of the purge fluid to enhance isolation of the processing fluids within each sector. The profile of the purge fluid is manipulated by controlling the shape and/or density of the purge curtain, independently between each processing sector.

In another aspect, a showerhead assembly is provided comprising a baffle plate having a plurality of fluid delivery ports for receiving one or more fluids. A faceplate is coupled to and spaced apart from the baffle plate to form a plenum, the faceplate having a plurality of injection ports. A purge member is disposed within the plenum and forms a plurality of separate processing sectors. The purge member includes a plurality of purge holes formed therethrough for conveying a purge fluid between the separate processing sectors and is configured to independently control a flow profile of the purge fluid between each processing sector.

In a further aspect, a method of processing a substrate is provided. Two or more different process fluids are injected through a segmented showerhead to process isolated regions on the substrate, each of the process fluids exhibiting at least one unique property. A purge fluid is conveyed between each of the two or more different process fluids to maintain isolation of the process fluids corresponding to the segmented regions. Flow of the purge fluid between each of the process fluids is independently varied. In some embodiments, flow of the purge fluid may be varied based on at least one unique property of each process fluid.

Other aspects of the present disclosure will become apparent from the following detailed description, taken in conjunction with the accompanying drawings. Several inventive embodiments are described below.

### BRIEF DESCRIPTION OF THE DRAWINGS

Embodiments of the present disclosure will be readily understood by the following detailed description in conjunction with the accompanying drawings, where like reference numerals designate like structural elements.

FIG. 1 illustrates a schematic diagram for implementing combinatorial processing and evaluation using primary, secondary, and tertiary screening;

FIG. 2 is a schematic diagram illustrating a general methodology for combinatorial process sequence integration that includes site isolated processing and/or conventional processing in accordance with one embodiment of the present disclosure;

FIG. 3 is a bottom-up exploded perspective view of a showerhead assembly in accordance with some embodiments of the present disclosure;

FIG. 4 is a top-down exploded perspective view of the showerhead assembly shown in FIG. 4;

FIGS. 5A and 5B are top and bottom perspective views, respectively, showing a faceplate in accordance with some embodiments of the present disclosure;

FIG. 6 is a simplified schematic diagram illustrating segmented regions on a substrate;

FIG. 7 is a contour plot illustrating the thickness of a film deposited across a substrate;

FIGS. 8A and 8B are top-down and bottom-up plan views, respectively, of the faceplate in accordance with one embodiment of the present disclosure; and

FIG. 9A-9C are partial, top-down plan views showing sample purge member configurations according to various embodiment of the present disclosure.

### DETAILED DESCRIPTION

Embodiments of the present disclosure provide apparatus and methods for delivering fluids to a semiconductor chamber for combinatorial processing. In some embodiments the apparatus is comprised of a showerhead assembly having a plurality of processing sectors separated by a purge member. The processing sectors are configured to receive one or more processing fluids for combinatorial processing on a substrate. Of particular advantage, the inventive showerhead assembly and system disclosed herein enable processing of a substrate using different processing fluids in the same showerhead assembly. The different processing fluids may exhibit different properties, such as but not limited to, vapor pressure, molecular weight, and the like. The processing sectors are isolated by a purge fluid conveyed through the purge member. The purge member is configured to selectively control the profile of the purge fluid to enhance isolation of the processing fluids within each sector. The profile of the purge fluid is manipulated by selectively controlling the shape and/or density of the purge curtain, independently between each processing sector. Additionally in some embodiments, the profile of the purge fluid is manipulated by varying the amount or flow rate of purge fluid flowing through the purge member.

In addition to depositing a layer of material over an entire substrate, the embodiments described below provide details for a multi-region processing system that enable processing a substrate in a combinatorial fashion. Thus, different regions of the substrate may have different properties, which may be due to variations of the materials, unit process conditions or parameters, and process sequences, etc. Within each region the conditions are preferably substantially uniform so as to mimic conventional full wafer processing, however, valid results can be obtained for certain experiments without this requirement. In some embodiments, the different regions are isolated so that there is no interaction between the different regions.

It should be appreciated that the combinatorial processing of the substrate may be combined with conventional processing techniques where substantially the entire substrate is uniformly processed, e.g., subjected to the same materials, unit processes and process sequences. The embodiments described herein can perform combinatorial deposition processing and conventional full substrate processing in the same chamber. Consequently, in one substrate processed in the same chamber, information concerning the varied processes and the interaction of the varied processes with the conventional processes can be evaluated. Accordingly, a multitude of data is available from a single substrate for a desired process.

The manufacture of semiconductor devices entails the integration and sequencing of many unit processing steps. As an example, semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference in their entirety. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference in their entirety.

HPC processing techniques have been successfully adapted to wet chemical processing such as etching, texturing, polishing, cleaning, etc. HPC processing techniques have also been successfully adapted to deposition processes such as sputtering, chemical vapor deposition (CVD), as well as atomic layer deposition (ALD) as described herein.

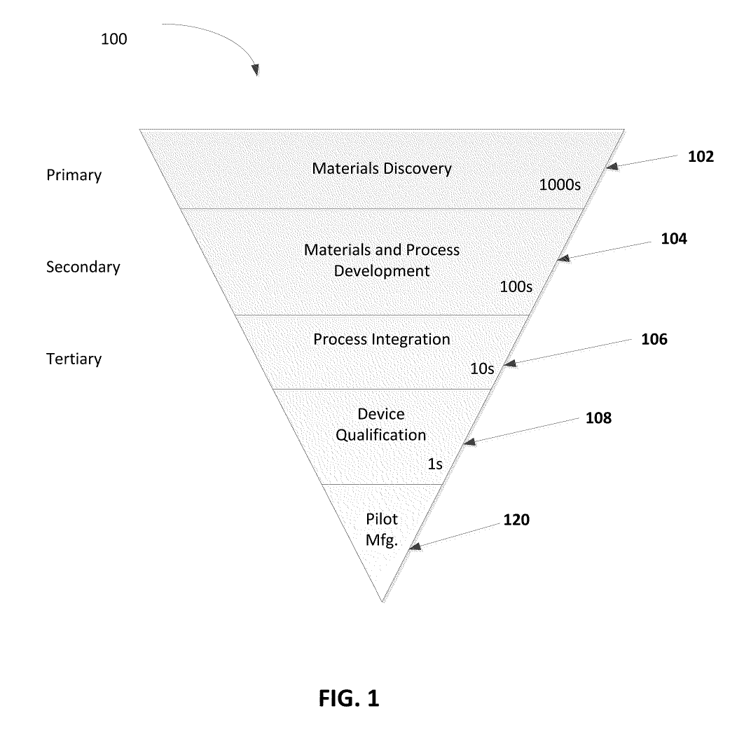

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a semiconductor device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

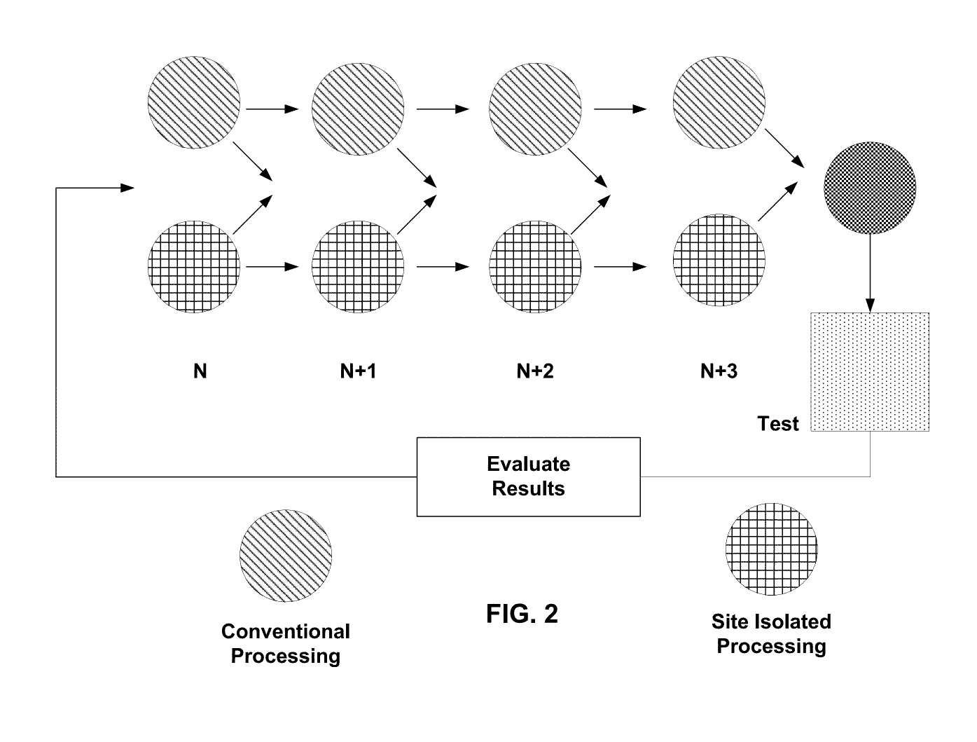

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

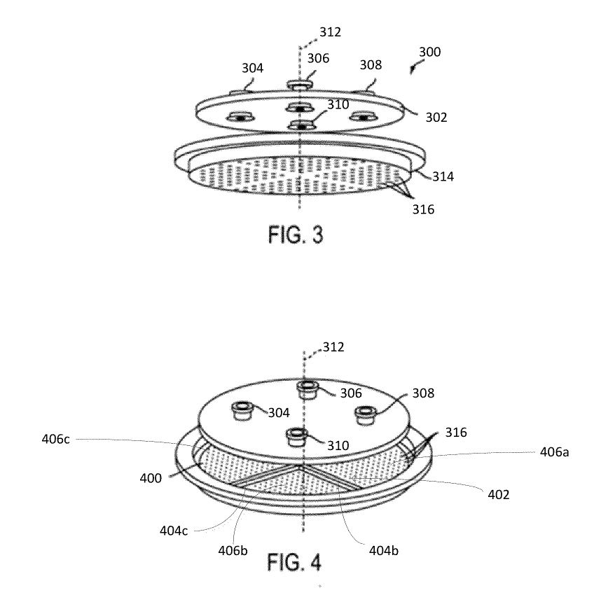

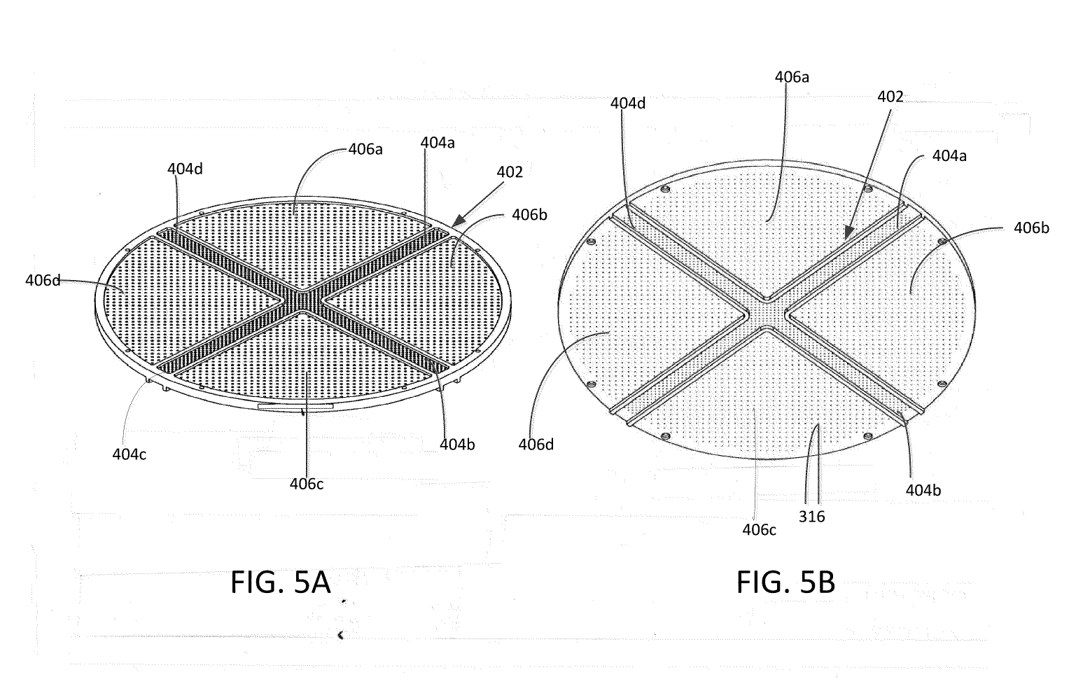

Referring to FIG. 3 and FIG. 4, simplified perspective views of a showerhead assembly 300 according to some embodiments of the present disclosure are shown. The showerhead assembly 300 is particularly suited for use in an integrated high productivity combinatorial (HPC) system as described in detail in pending U.S. patent application Ser. No. 12/205,578, filed on Sep. 5, 2008, which is herein incorporated by reference in its entirety.

In the exemplary embodiment, showerhead assembly 300 includes baffle plate 302 with a plurality of fluid delivery ports 304, 306, 308, 310 formed therethrough. In the illustrative example the baffle plate 302 is radially symmetric about a central axis 312. Fluid delivery ports 304, 306, 308, 310 are coupled to fluid delivery supply lines (not shown) and are configured to receive one or more processing fluids.

A faceplate 314 is coupled to and spaced apart from the baffle plate 302, forming a plenum 400 therebetween (FIG. 4). Generally, the faceplate 314 is aligned with the baffle plate 302 and is radially symmetric about central axis 312. The faceplate 314 includes a plurality of injection ports 316 extending therethrough. The injection ports 316 are configured to deliver processing fluids to a substrate disposed adjacent the showerhead assembly 300.

The faceplate 314 is coupled to the baffle plate 302 using any suitable means, such as for example, by fasteners, welding and the like. The showerhead assembly 300 may be made from any material suitable for semiconductor processing, such as for example, from stainless steel, aluminum, anodized aluminum, ceramic, and the like.

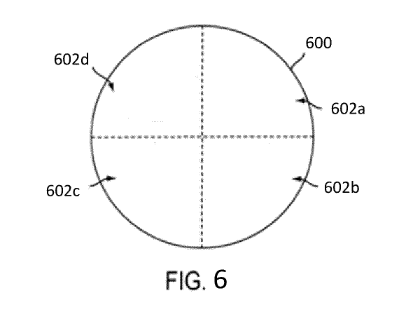

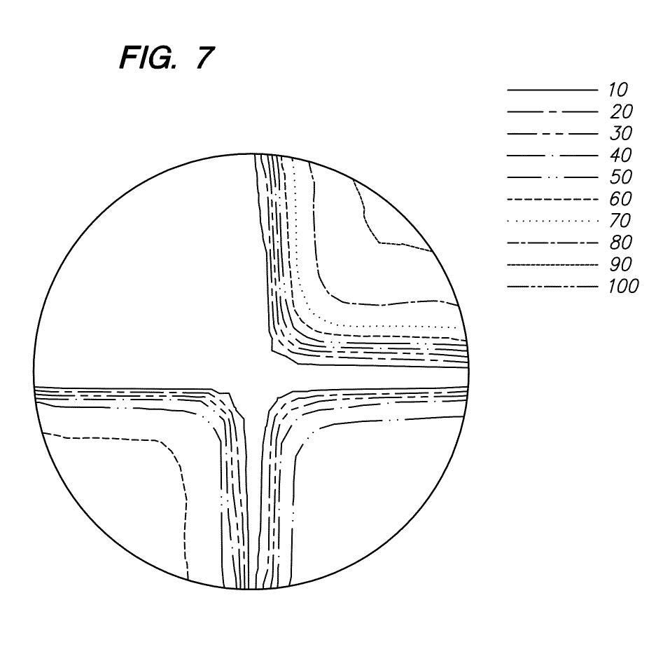

Disposed within the plenum 400 is a purge member 402. The purge member 402 is configured to form a plurality of separate processing sectors. FIGS. 5A and 5B illustrate one example of the purge member 402 which includes channels 404a-404b that extend in two orthogonal directions across the diameter of the faceplate 314 to create four separate processing sectors 406a-406d. In FIG. 6, a wafer or substrate 600 is disposed below the showerhead injector 300 and the four separate processing sectors 406a-406d in the showerhead 300 correspond to four separate regions or sectors 602a-602d on substrate 600. While four separate processing sectors are shown, any number of separate processing sectors may be used, such as for example and without limitation, 2, 3 and 6 processing sectors. Substrate 600 may be a conventional round 200 mm, 300 mm, or any other larger or smaller substrate/wafer size. In other embodiments, substrate 600 may be a square, rectangular, or other shaped substrate. Substrate 600 may be without limitation a blanket substrate, a coupon (e.g., partial wafer), or a patterned substrate having predefined regions.

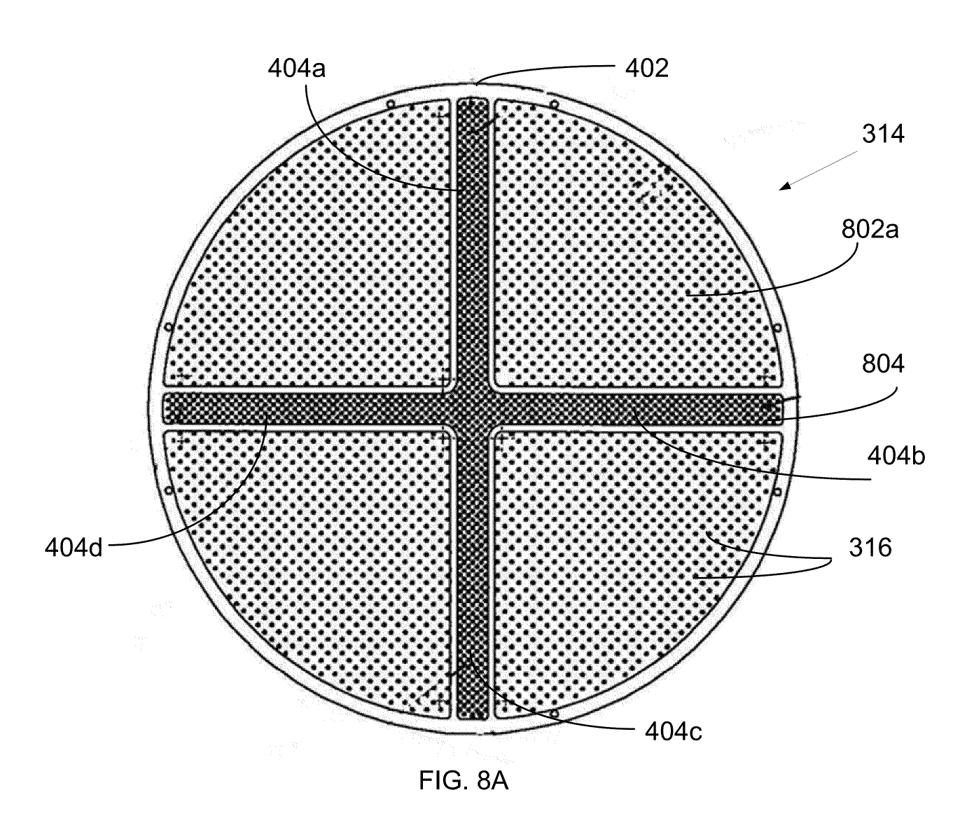

Parallel delivery of different process fluids in a controlled manner to specific processing areas or sectors on a substrate such as to regions 602a-602d is difficult to achieve. Control of deposition is achieved by embodiments of the present disclosure as illustrated in FIG. 7, a contour plot of deposited film thickness across a substrate 700 using different processing gases in three sectors. As is shown, the flow profile of the processing gases are well controlled across the sectors, with each sector being completely isolated from an adjacent sector. In the upper left quadrant, where no processing gas was present, no deposition occurred thus demonstrating that complete isolation is achieved such that deposition may be excluded in a region. In addition to isolating the various sectors, FIG. 7 also shows control of the thickness of the deposited layer across a specific sector. For example, the contour lines near the center of the wafer represent relatively thick deposition thickness (such as for example 100A) and the contour lines near the edge of the wafer represent a thinner layer of deposition (such as for example 10A).

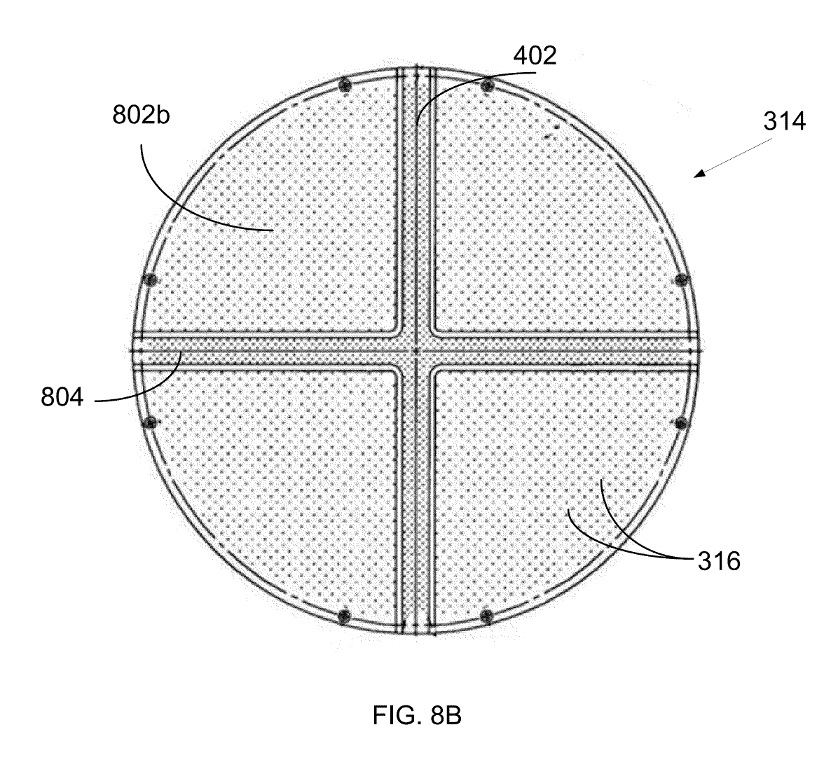

Referring to FIGS. 8A and 8B, the faceplate 314 has top 802a and bottom 802b surfaces. The top surface 802a forms the bottom region of the plenum 400. The bottom surface 802b is disposed adjacent the substrate (not shown) to be processed. In some embodiments, the purge member 402 is formed in the faceplate 314. The purge member 402 may include raised edges on the top surface 802a of the faceplate 314 in order to further isolate the processing sectors in the plenum 400. On the bottom surface 802b of faceplate 314, edges of the purge member 402 may be raised to further promote isolation of the processing fluids as the fluids exit the showerhead and flow towards the substrate. Alternatively, the purge member 402 is substantially flush with either the top 802a or bottom 802b surfaces, or with both. In an alternative embodiment, the purge member 402 is comprised of a separate member that is attached to the faceplate 314.

The fluid delivery ports 304, 306, 308, 310 are configured to receive various processing fluids and convey the fluids to corresponding processing sectors 404a-404d in the showerhead assembly. The purge member 402 includes a plurality of purge holes 804 formed through the purge member 402 for conveying one or more purge fluids as shown in FIG. 8A and FIG. 8B. The purge member 402 and purge holes 804 promote separation and isolation of processing fluids in the separated processing sectors such that processing occurs at the corresponding regions on the substrate 600.

Any suitable purge fluid may be used, and generally, but not necessarily, will be comprised of a gas or vapor. Suitable gases include inert gases such as argon, nitrogen, helium, xenon, and the like and mixtures thereof.

The purge member 402 includes channels 404a-404d that extend across the partial, substantial, or entire diameter of the faceplate 314, and divide the faceplate 314 into the plurality of processing sectors 406a-406d (FIGS. 5A and 5B) In the illustrative example the channels 404a-404d extend in two orthogonal directions across the diameter of the faceplate 314; however as discussed above, many other configurations are possible and within the scope of the present disclosure.

Purge holes 804 are formed in the channels 404a-404d and configured to convey one or more purge fluid(s) between one or more of the processing sectors. This flow of purge fluid is sometimes referred to as a “purge curtain.” The purge member 402 may be configured to selectively control the flow profile of the purge fluid to enhance isolation of the processing fluids within each sector. The flow profile of the purge fluid may be manipulated by selectively controlling the shape and/or density of the purge curtain, independently between each processing sector. Of particular advantage, the inventive showerhead of the present disclosure enables the parallel delivery of different processing fluids within one showerhead. For example, different processing fluids often exhibit unique or particular properties that can influence their fluid dynamics. In some embodiments, flow of the purge fluid between each of the processing fluids is independently varied in order to accommodate the different flow or fluid dynamics of the different processing fluids. In some embodiments, flow of the purge fluid may be varied based on at least one unique or particular property of each processing fluid, such as but not limited to: molecular weight, vapor pressure, carrier gas flow rate or carrier gas flow time.

The purge member is configured to selectively control the flow profile of purge fluid independently between each processing sector. In one embodiment, the flow profile of the purge fluid is controlled by manipulating the density of the purge holes 804. As illustrated in the exemplary embodiment, the density of purge holes 804 is greater than the density of injection ports 316. The density of purge holes may be characterized as the number of holes per unit area. In the instance where the distribution of purge holes is non-uniform, then multiple values may be used to characterize the density. The density of the purge holes 804 is not limited, and any suitable number may be used that is sufficient to provide the desired isolation of processing fluid between the sectors. In some embodiments, the density of the purge holes 804 is twice the density of the injector ports 316.

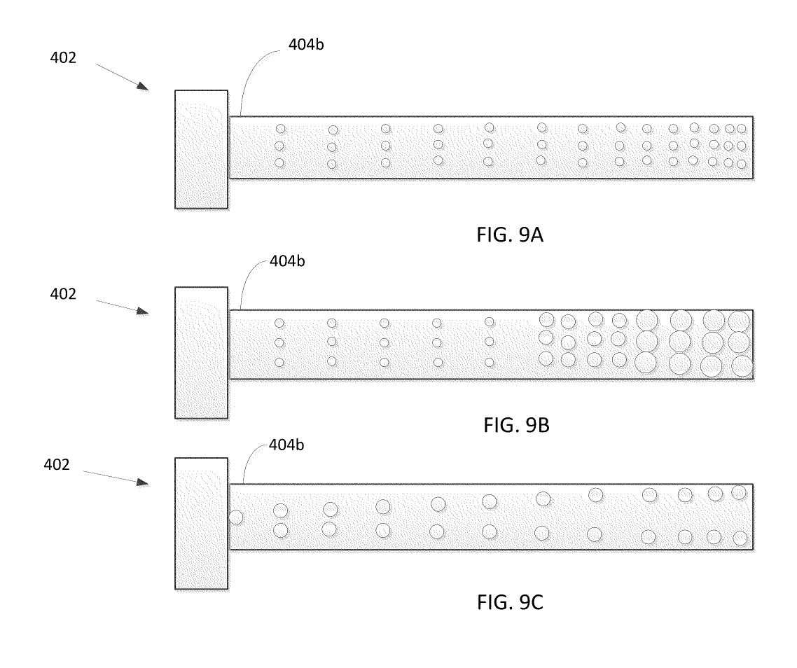

The density of the purge holes 804 are generally configured to control the flow profile of the purge fluid between sectors and may be tailored for different processing fluids, particularly when the fluid is a gas. Different processing fluids will have different properties such as molecular weights, vapor pressure and the like, and in such instance the fluid flow dynamics of each processing fluid will be different. Of particular advantage, the density of the purge holes 804 may be varied to accommodate the different flow dynamics of each processing fluid. As shown in FIG. 9A-9C, the profile of the purge fluid may be selectively controlled in a number of ways, such as for example (and without limitation) by: varying the size of the purge holes 804, varying the distribution of the purge holes 804, varying the location of the purge holes, varying the pattern of the purge holes, and the like. In another embodiment, the location of the purge fluid port in the top baffle may be placed selectively such that flow rate of purge fluid is greater in a desired region of the purge member. In some embodiments the density of the purge holes 804 will be greater towards the periphery of the faceplate than near the center. Moreover, one or more of the channels of the purge member 402 may contain a different arrangement and/or density of purge holes, thereby providing selective control of the purge fluid profile independently between one of more of the processing sectors.

In operation, processing fluids such as chemical precursors, reactants, or reagents may be delivered independently or together, separated by the purge fluid, and thus enable selective control or modulation of the deposited film properties in the separate processing sectors. Film thickness, film sequence, film stacking, film composition and the like can be varied in a site-isolated manner. In addition to site isolated variation, chamber wide process variations can include without limitation, flow rates, chamber pressures, conductance, pulse duration, precursor or reagent source temperature, showerhead temperature, chamber body temperature, and the like.

The showerhead assembly described herein may be used in any type of chamber or combination of chambers and the description herein is merely illustrative of one possible combination and not meant to limit the potential chamber or processes that can be supported to combine combinatorial processing or combinatorial plus conventional processing of a substrate or wafer. A plurality of methods, such as but not limited to combinatorial CVD and ALD processes, may be employed to deposit material upon the substrate employing combinatorial processes.

The invention has been described in relation to particular examples, which are intended in all respects to be illustrative rather than restrictive. Various aspects and/or components of the described embodiments may be used singly or in any combination. It is intended that the specification and examples be considered as exemplary only, with a true scope and spirit of the invention being indicated by the claims.

What is claimed is:

1. An apparatus for delivering fluids to a chamber, comprising:
a fluid supply system; and
a showerhead assembly coupled to the fluid supply system, the showerhead assembly comprising a plurality of processing sectors, wherein each of the plurality of processing sectors is separated by a purge member, wherein the purge members extend radially from a center of the showerhead to a periphery of the showerhead; and
a plurality of purge holes formed in the purge member, and wherein the plurality of purge holes vary in at least one of the hole size or the spatial distribution of holes

2. The apparatus of claim 1 wherein the purge hole size or the spatial distribution of the purge holes varies radially along the purge member.

3. The apparatus of claim 1 wherein the spatial density of purge holes increases in the radial direction from a center of the showerhead assembly to a periphery of the showerhead assembly.

4. A showerhead assembly, comprising:
a baffle plate having a plurality of fluid delivery ports for receiving one or more fluids;
a faceplate coupled to and spaced apart from the baffle plate to form a plenum,the faceplate having a plurality of injection ports; and
a purge member disposed within the plenum, the purge member forming a plurality of separate processing sectors, the purge member comprised of a plurality of purge channels extending across the faceplate in a radial direction from a center of the showerhead assembly to a periphery of the showerhead assembly, and a plurality of purge holes formed through the purge channels for conveying a purge fluid between the separate processing sectors, and wherein the purge holes are non-uniformly spaced.

5. The showerhead assembly of claim 4 wherein the spatial density of purge holes are greater at a periphery of the showerhead assembly than at a center of the showerhead assembly.

6. The showerhead assembly of claim 5 wherein the purge member comprises three or more purge channels.

7. The showerhead assembly of claim 5 wherein the purge member comprises four purge channels.

8. A method of processing a substrate, comprising the steps of:
injecting two or more different processing fluids through a segmented showerhead to process isolated regions on the substrate, each of the processing fluids exhibiting at least one unique property; and
conveying a purge fluid between each of the two or more showerhead segments to maintain isolation of the processing fluids, where flow of the purge fluid between each of the showerhead segments is independently varied.

9. The method of claim 8 wherein the isolation of the two or more different processing fluids corresponds to the isolated regions on the substrate.

10. The method of claim 8 wherein the at least one unique property of each process fluid is comprised of one or more of: molecular weight, vapor pressure, carrier gas flow rate, or carrier gas flow time.

11. The method of claim 10 wherein the two or more different processing fluids exhibit at least two different molecular weights.

12. The method of claim 10 wherein the two or more different processing fluids exhibit at least two different vapor pressures.

13. The method of claim 8 wherein the flow of purge fluid is greater at a periphery of the substrate than at a center of the substrate.
